(19) United States
(12) Patent Application Publication
(10) Pub. No.: US 2024/0242989 A1
(43) Pub. Date: Jul. 18, 2024

(54) GRID STRUCTURE FOR FIXING SPECIMEN

(71) Applicant: SAMSUNG ELECTRONICS CO., LTD., SUWON-SI (KR)

(72) Inventors: Yeoseon Choi, Suwon-si (KR); Unki Kim, Suwon-si (KR)

(21) Appl. No.: 18/406,925

(22) Filed: Jan. 8, 2024

(30) Foreign Application Priority Data
Jan. 12, 2023 (KR) 10-2023-0004929

(51) Int. Cl. H01L 21/673; H01J 37/20

(52) U.S. Cl. CPC H01L 21/67336; H01J 37/20

(57) ABSTRACT

The present disclosure describes example apparatuses (e.g., grid structures) for fixing or holding a specimen, where the grid structure is formed by alternately stacking different layers (e.g., silicon (Si) layers and silicon germanium (SiGe) layers). For example, the alternate layers may be visually distinguishable from each other and may have a configured thickness. As such, based on the visual distinguishability between layers and the configured thickness for each layer, the grid structure may be used to adjust the magnification during inspection of the specimen. For example, the stacked layers may serve as a scale to control the magnification of the electron microscope while inspecting the specimen based on the configured or known thickness of the layers. Additionally, the orientation of the stacked layers may be used as a reference when a specimen is inspected.

### CROSS-REFERENCE TO RELATED APPLICATION

This application is based on and claims priority under 35 U.S.C. § 119 to Korean Patent Application No. 10-2023-0004929, filed on Jan. 12, 2023, in the Korean Intellectual Property Office, the disclosure of which is incorporated by reference herein in its entirety.

### BACKGROUND

The present disclosure relates to a grid structure for fixing a specimen, and more specifically, to a grid structure for fixing a specimen observed through an electron microscope.

In general, a plurality of unit processes may be continuously performed in a semiconductor device manufacturing process. For example, wafers are manufactured as chips (e.g., semiconductor devices) by repeatedly performing different unit processes, such as photographic processes, diffusion processes, etching processes, and deposition processes. In some examples, an analysis process is carried out between performing the unit processes, and through this analysis process, it is identified whether a unit process is normal. Structural analysis devices that perform the analysis process include equipment, such as an electron microscope, that observe the structure and crystallinity of crystals using electron diffraction.

The electron microscope is equipment which, in part, analyzes an image by passing electrons accelerated over 200 kiloelectronvolts (keV) through a specimen (e.g., where the specimen is manufactured to a thickness of 100 nanometers (nm) or less). In some examples, the electron microscope may be capable of analyzing a crystal structure by forming a diffraction pattern by diffracting electrons on a crystal plane when the electrons pass through the specimen. A structure (e.g., grid structure) may be used to hold or fix the specimen in place for the electron microscope or other equipment to perform and/or assist with analyses on the specimen.

### SUMMARY

The present disclosure provides a grid structure for fixing a specimen that may set a magnification and simultaneously inspect the specimen by forming a scale on a protrusion that fixes the specimen.

In addition, the present disclosure provides a grid structure for fixing a specimen in which the scale of the protrusion is formed into a single crystal to be used as a structure as a reference.

In addition, the tasks to be solved by the technical idea of the present disclosure are not limited to the tasks mentioned above, and it may be clearly understood that other tasks may be applied to the present disclosure by one of ordinary skill in the art from the following description.

The present disclosure provides a grid structure for fixing a specimen as follows in order to achieve a technical task.

According to an aspect of the present disclosure, there is provided an apparatus (e.g., a grid structure for fixing a specimen) including a body and a plurality of protrusions protruding in a vertical direction on a top surface of the body, wherein at least one of the protrusions includes a first region in which at least one first layer and at least one second layer are alternately stacked in the vertical direction, and the at least one first layer and the at least one second layer each have a first thickness in the vertical direction (e.g., the at least one first layer and the at least one second layer each have a same vertical thickness).

According to another aspect of the present disclosure, there is provided an apparatus (e.g., a grid structure for fixing a specimen) including a body and a plurality of protrusions protruding in a vertical direction on a top surface of the body, wherein at least one of the protrusions includes a first region in which at least one first layer and at least one second layer are alternately stacked in the vertical direction, the at least one first layer includes silicon germanium (SiGe) and the at least one second layer includes silicon (Si), each of the at least one first layer and the at least one second layer has a first thickness in the vertical direction (e.g., the at least one first layer and the at least one second layer each have a same vertical thickness), and the first layer and the second layer are formed of a single crystal.

According to another aspect of the present disclosure, there is provided an apparatus (e.g., a grid structure for fixing a specimen) including a body and a plurality of protrusions (e.g., at least five protrusions) protruding in a vertical direction on a top surface of the body, wherein each of the protrusions includes a first region in which at least one first layer and at least one second layer are alternately stacked in the vertical direction, the at least one first layer comprises SiGe and the at least one second layer comprises Si, each of the at least one first layer and the at least one second layer has a first thickness in the vertical direction (e.g., the at least one first layer and the at least one second layer each have a same vertical thickness), and the at least one first layer and the at least one second layer are formed of a single crystal.

### BRIEF DESCRIPTION OF THE DRAWINGS

Embodiments of the present disclosure will be more clearly understood from the following detailed description taken in conjunction with the accompanying drawings in which:

FIG. 1 is a cross-sectional view schematically illustrating a grid structure for fixing a specimen according to embodiments;

FIG. 2 is an enlarged view of a portion AA of the grid structure for fixing a specimen of FIG. 1;

FIG. 3 is a cross-sectional view schematically illustrating a grid structure for fixing a specimen according to embodiments;

FIG. 4 is a cross-sectional view schematically illustrating a grid structure for fixing a specimen according to embodiments;

FIG. 5 is a cross-sectional view schematically illustrating a grid structure for fixing a specimen according to embodiments;

FIG. 6 is a cross-sectional view schematically illustrating a grid structure for fixing a specimen according to embodiments;

FIG. 7 is a cross-sectional view schematically illustrating a grid structure for fixing a specimen according to embodiments;

FIG. 8 is a cross-sectional view schematically illustrating a grid structure for fixing a specimen according to embodiments; and

FIG. 9 is a cross-sectional view schematically illustrating a grid structure for fixing a specimen according to embodiments.

### DETAILED DESCRIPTION

Hereinafter, embodiments of the present disclosure will be described in detail with reference to the accompanying drawings. The same reference numerals are used for the same components in the drawings, and redundant descriptions thereof are omitted.

As described herein, electron microscopes may be used to perform structural analyses and/or other analysis processes of specimens. For example, electron microscopes may be capable of analyzing or facilitating analysis of the structure of a specimen based on electron diffraction (e.g., forming a diffraction pattern by diffracting electrons on a crystal plane when electrons pass through the specimen). In some examples, the analysis processes performed by electron microscopes may occur in between different unit processes in a semiconductor device manufacturing process (e.g., photographic processes, diffusion processes, etching processes, deposition processes, etc.) to ensure the different unit processes are performed normally and correctly. For example, electron microscopes may be used to observe the structure and crystallinity of crystals of a specimen at different stages of a manufacturing process for the specimen (e.g., in between each of the different unit processes). Additionally or alternatively, electron microscopes may generally be used to observe the structure and crystallinity of crystals of a specimen based on passing electrons (e.g., accelerated at over 200 kiloelectronvolts (keV)) through the specimen.

When inspecting a specimen using an electron microscope, a structure (e.g., grid structure) may be used to hold or fix the specimen in place to allow for the electrons to be passed through the specimen. However, in some cases, the structure may solely be used to hold the specimen, thereby allowing opportunities for enhancements of the structure to enable more efficient use of equipment (e.g., an electron microscope) capable of performing analyses on the specimen. As such, enhancements to the structure configured to hold or fix the specimen in place may be desired.

Accordingly, as described herein, a grid structure is provided for fixing or holding a specimen, where the grid structure is formed by alternately stacking different layers (e.g., silicon (Si) layers and silicon germanium (SiGe) layers, similar to a ruler scale). For example, the alternate layers may be visually distinguishable from each other and may have a configured thickness (e.g., each layer may have a same thickness as the other layers within a given region, different regions of the stacked layers may have respective configured thicknesses for each layer within the region, etc.). As such, based on the visual distinguishability between layers and the configured thickness for each layer, the grid structure may be used to adjust the magnification during inspection of the specimen. For example, the stacked layers may serve as a scale to control the magnification of the electron microscope while inspecting the specimen based on the configured or known thickness of the layers. Additionally, the orientation of the stacked layers (e.g., a crystal formed from the stacked layers) may be used as a reference when a specimen is inspected by forming a first layer and a second layer of the alternating layers as a single crystal layer.

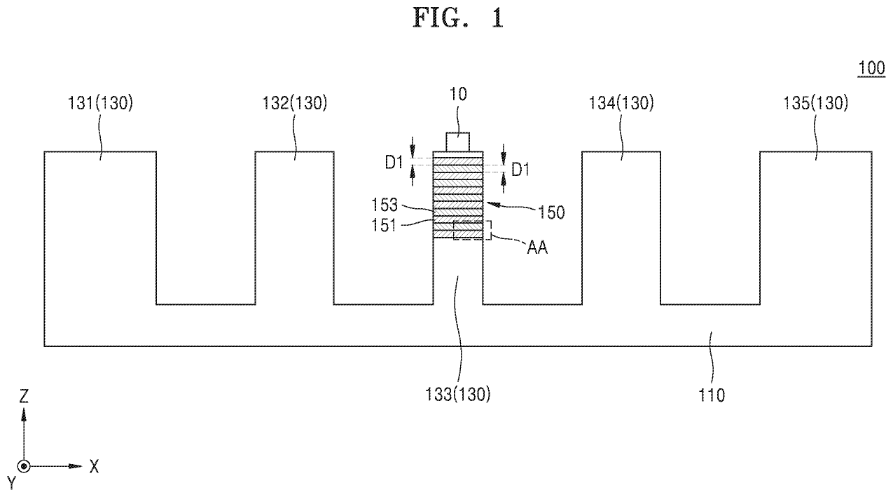

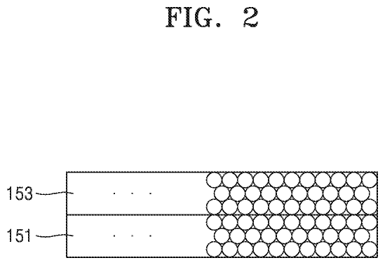

FIG. 1 is a cross-sectional view schematically illustrating a grid structure 100 for fixing a specimen according to embodiments described herein. FIG. 2 is an enlarged view of a portion AA of the grid structure 100 for fixing a specimen of FIG. 1.

Referring to FIGS. 1 and 2, the grid structure 100 (e.g., for fixing a specimen) may include a body 110 and one or more protrusions 130.

The grid structure 100 may be a structure for fixing a specimen 10 to be observed, for example, through an electron microscope. The electron microscope may be, for example, a Transmission Electron Microscope (TEM), a Scanning Electron Microscope (SEM), and/or a Scanning Transmission Electron Microscope (STEM).

In some embodiments, the specimen 10 may be a specimen formed using a focused ion beam (FIB) method.

The specimen 10 may be fixed to the grid structure 100 and mounted on a specimen holder (not shown). Subsequently, the specimen 10 may be inspected using the electron microscope as the specimen holder is loaded into an electron microscope facility.

In some examples, the specimen holder may be a device for accommodating one or more specimens to load the specimen 10 into an electron microscope. For example, the specimen holder may be a specimen holder that may also be used in a TEM and/or an SEM. Additionally or alternatively, the specimen holder may be used in Energy Dispersive Spectrometer (EDS) analysis for measuring the structure and chemical composition of the specimen 10 by analyzing an X-ray in which an electron beam is irradiated onto and reacted with the specimen 10 through an EDS (not shown), which is provided in the electron microscope.

The electron microscope may irradiate light toward a specimen 10 fixed to the grid structure 100. At least a part of the light irradiated onto the specimen 10 enters an electron microscope after passing through the specimen 10, and the electron microscope may measure and analyze the input light.

According to embodiments, the body 110 of the grid structure 100 may have a flat bottom surface.

In the following figures, the X-axis direction and the Y-axis direction represent directions parallel to the bottom surface of the body 110, and the X-axis direction and the Y-axis direction may be perpendicular to each other. The Z-axis direction may indicate a direction perpendicular to a top surface or a bottom surface of the body 110. In other words, the Z-axis direction may be a direction perpendicular to the X-Y plane.

In the following figures, a first horizontal direction, a second horizontal direction, and a vertical direction may be understood as follows: the first horizontal direction may be understood as an X-axis direction; the second horizontal direction may be understood as a Y-axis direction; and the vertical direction may be understood as a Z-axis direction.

Each of the protrusions 130 may have a shape protruding in the vertical direction Z from the top surface of the body 110. In some embodiments, a plurality of protrusions 130 may be provided. For example, the protrusions 130 may include a first protrusion 131, a second protrusion 132, a third protrusion 133, a fourth protrusion 134, and a fifth protrusion 135. That is, in some embodiments, five protrusions 130 may be provided on the body 110 of the grid structure 100.

In the figures of the present disclosure, although five protrusions 130 are illustrated, embodiments are not limited thereto, and a number of protrusions 130 may be provided that is less than or greater than five (e.g., one protrusion, two protrusions, six protrusions, etc.).

In some embodiments, the plurality of protrusions 130 may have thickness in the first horizontal direction X that are the same as each other. However, the embodiments are not limited thereto, and the plurality of protrusions 130 may not have the same thicknesses in the first horizontal direction X. For example, the plurality of protrusions 130 may each have different thicknesses in the first horizontal direction X. Additionally or alternatively, the first protrusion 131 and the fifth protrusion 135 may have a same thickness in the first horizontal direction X, the second protrusion 132 and the fourth protrusion 134 may have a same thickness in the first horizontal direction X, and the third protrusion 133 may have a thickness in the horizontal direction X that is different from those of the first protrusion 131, the second protrusion 132, the fourth protrusion 134, and the fifth protrusion 135.

In some embodiments, the specimen 10 may be fixed on the top surface of each of the protrusions 130. For example, the specimen 10 may be fixed on the top surface of each of the protrusions 130 through an adhesive.

With the specimen 10 fixed to the top surface of the protrusions 130, the electron microscope may be located at a location spaced apart from the specimen 10 in the second horizontal direction Y, and the specimen 10 may be examined and analyzed by irradiating light in the second horizontal direction Y toward the specimen 10.

As described herein, one or more first layers 151 and one or more second layers 153 may be alternately stacked on at least one of the protrusions 130. For example, after a first instance of the first layer 151 is formed, a first instance of the second layer 153 may be formed on the first instance of the first layer 151, an additional instance of the first layer 151 may be stacked again on the first instance of the second layer 153, an additional instance of the second layer 153 may be stacked again on the additional instance of the first layer 151, etc. The number of first layers 151 and the number of second layers 153 alternately stacked may be a plurality, respectively. A region in which at least one first layer 151 and at least one second layer 153 are alternately stacked on one of the protrusions 130 may be defined as a first region 150. As shown in the example of FIG. 1, the first region 150 may be formed in the third protrusion 133.

The first layer 151 and the second layer 153 may be formed of different materials. For example, in some embodiments, the first layer 151 may include SiGe, and the second layer 153 may include Si. However, the embodiments are not limited thereto, as long as each of the materials constituting the first layer 151 and the second layer 153 may be distinguished from each other (e.g., through an electron microscope).

The first layer 151 and the second layer 153 may be formed of a single crystal. As shown in FIG. 2, each of the first layer 151 and the second layer 153 may be formed of a single crystal and may be formed to have a certain directionality. Additionally, each of the first layer 151 and the second layer 153 may have a flat top surface and a flat bottom surface. In some examples, in order for the first layer 151 and the second layer 153 to have the characteristics described above, the first layer 151 and the second layer 153 may be formed by epitaxial growth.

In some embodiments, the first layer 151 and the second layer 153 may be visually distinguished from each other. For example, the first layer 151 and the second layer 153 may be distinguished from each other by color. As the first layer 151 and the second layer 153 are visually distinguished with the naked eye from each other, the first layers 151 and the second layers 153 that are alternately stacked may function as a scale. The meaning of being visually distinguished with the naked eye may include being visually distinguished through an electron microscope. As described herein, the scale may be understood as the first layer 151 or the second layer 153 unless specifically defined.

The first layer 151 and the second layer 153 may have the same thickness in the vertical direction Z. That is, each of the plurality of first layers 151 and the plurality of second layers 153 alternately stacked upon each other may have the same thickness in the vertical direction Z.

Based on the first layer 151 and the second layer 153 having the same thickness along with the first layer 151 and the second layer 153 being visually distinguished from each other, the protrusion 130 that includes the first layer 151 and the second layer 153 that are alternately stacked one after another may serve as a scale to control the magnification of the electron microscope.

In some embodiments, the first layer 151 and the second layer 153, which are alternately stacked, may have the same shape as a scale of a ruler. For example, the thicknesses of the first layer 151 and the second layer 153 may be formed to be about 10 nm while forming the first layer 151 and the second layer 153. Accordingly, the thickness of one scale may be understood as about 10 nm.

Based on the specimen 10 being fixed on the top surface of the protrusion(s) 130 where the first layer 151 and the second layer 153 serving as a scale are formed, the magnification of the electron microscope may be adjusted based on the first layer 151 and the second layer 153 adjacent to the specimen 10 while inspecting the specimen 10 through an electron microscope.

In some embodiments, each of the first layer 151 and the second layer 153 may have a first thickness D1. The first thickness D1 may range from about 1 nm to about 100 nm. When the first thickness D1 is less than about 1 nm, the gap between adjacent first layers 151, adjacent second layers 153, or adjacent first layers 151 and second layers 153 may be too narrow, making it difficult for the first layers 151 and the second layers 153 to serve as the scales. Additionally or alternatively, when the first thickness D1 is greater than about 100 nm, the gap between adjacent first layers 151, adjacent second layers 153, or adjacent first layers 151 and second layers 153 may widen, making it difficult to control the magnification of the specimen 10 through the gap.

In some embodiments, each of the first layers 151 and the second layers 153 may be formed as a single crystal. Based on being formed as a single crystal, the crystals inside the first layers 151 may have the same direction, and similarly, the crystals inside the second layers 153 may have the same direction, as is shown in the example of FIG. 2. Therefore, when a reference is required while inspecting and analyzing the specimen 10 fixed on the protrusion(s) 130 through an electron microscope, the protrusion(s) 130 may be used as a reference structure based on the direction of the crystals formed in the first layers 151 and the second layers 153.

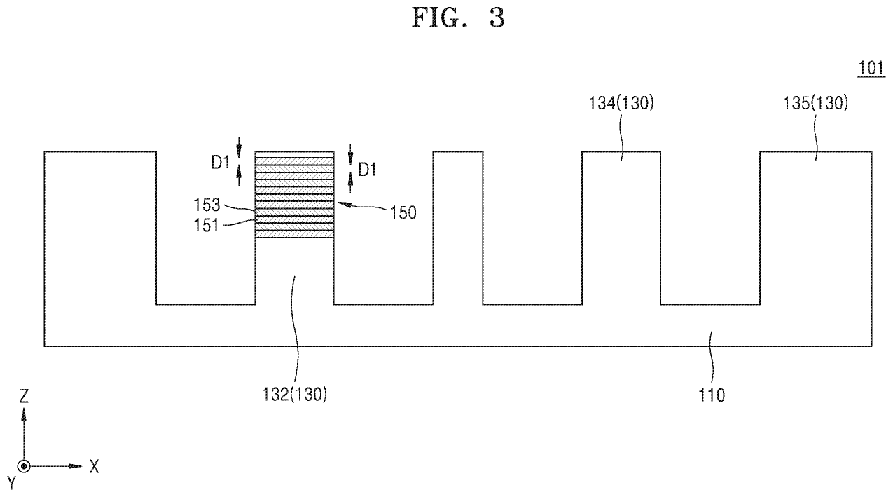

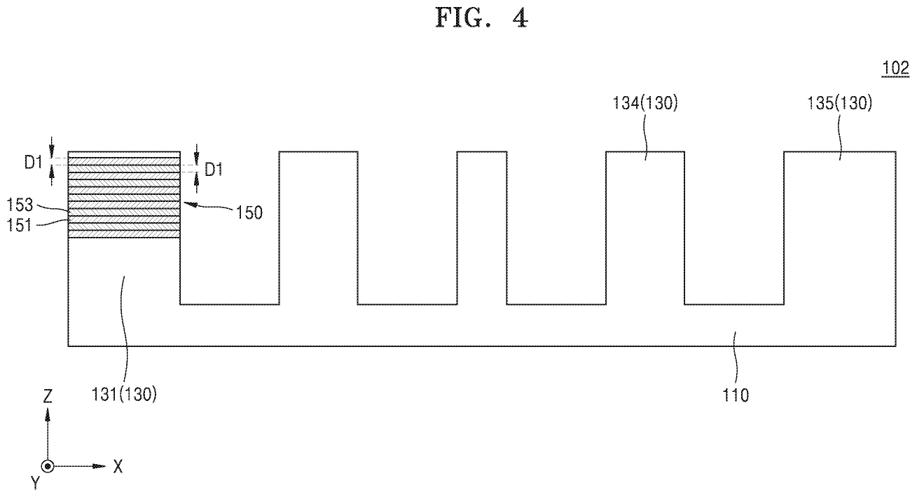

FIG. 3 is a cross-sectional view schematically illustrating a grid structure 101 for fixing a specimen according to embodiments. FIG. 4 is a cross-sectional view schematically illustrating a grid structure 102 for fixing a specimen according to embodiments. The grid structure 101 as illustrated in the example of FIG. 3 and the grid structure 102 as illustrated in the example of FIG. 4 may represent aspects of or may be represented by aspects of the grid structure 100 as described with reference to FIGS. 1 and 2. As such, redundant description between the grid structure 100 of FIGS. 1 and 2, the grid structure 101 of FIG. 3, and the grid structure 102 of FIG. 4 is omitted and the differences therebetween are mainly explained.

Referring to FIGS. 3 and 4, the grid structure 101 and the grid structure 102, respectively, may each include a body 110 and one or more protrusions 130. Each of the protrusions 130 may have a shape protruding in the vertical direction Z from the top surface of the body 110.

In some embodiments and in the examples of FIGS. 3 and 4, a plurality of protrusions 130 may be provided. For example, the protrusions 130 may include a first protrusion 131, a second protrusion 132, a third protrusion 133, a fourth protrusion 134, and a fifth protrusion 135. However, although five protrusions 130 are illustrated, embodiments are not limited thereto, and a number of protrusions 130 may be provided that is less than or greater than five.

As described herein, one or more first layers 151 and one or more second layers 153 may be alternately stacked on at least one of the protrusions 130 (e.g., after the first layer 151 is formed, the second layer 153 may be formed on the first layer 151, the first layer 151 may be stacked again on the second layer 153, etc.). The number of first layers 151 and the number of second layers 153 alternately stacked may include a plurality of layers, respectively. A region in which at least one first layer 151 and at least one second layer 153 are alternately stacked may be defined as a first region 150.

The first region 150 described with reference to FIG. 1 may be formed in any one of the plurality of protrusions 130. For example, as shown in the example of FIG. 3, the first region 150 may be formed in the second protrusion 132. Additionally or alternatively, as shown in the example of FIG. 4, the first region 150 may be formed in the first protrusion 131. In some embodiments, the protrusion 130 in which the first region 150 is formed is not limited thereto, and the first region 150 may be formed in the fourth protrusion 134 and/or the fifth protrusion 135 as well.

That is, the position of the protrusion 130 in which the first region 150 is formed may not be fixed to any one of the first protrusion 131, the second protrusion 132, the third protrusion 133, the fourth protrusion 134, and/or the fifth protrusion 135. Accordingly, the first region 150 that serves as a scale and reference may be formed in any desired protrusion 130 as necessary.

In some embodiments, the thicknesses in the first horizontal direction X of the first protrusion 131, the second protrusion 132, the third protrusion 133, the fourth protrusion 134, and the fifth protrusion 135 may be different. Subsequently, the ratio of the thicknesses in the vertical direction Z and the first horizontal direction X may be different depending on which protrusion 130 the first region 150 is formed.

The absolute value of the first thickness D1, which is the thickness of the first layer 151 and the second layer 153, may be determined based on the protrusion 130 on which the first region 150 is formed. For example, the absolute value of the thickness in the first horizontal direction X of the top surface of each protrusion 130 may be known, and thus, the magnification according to the first horizontal direction X may be adjusted while inspecting and analyzing a specimen through the electron microscope.

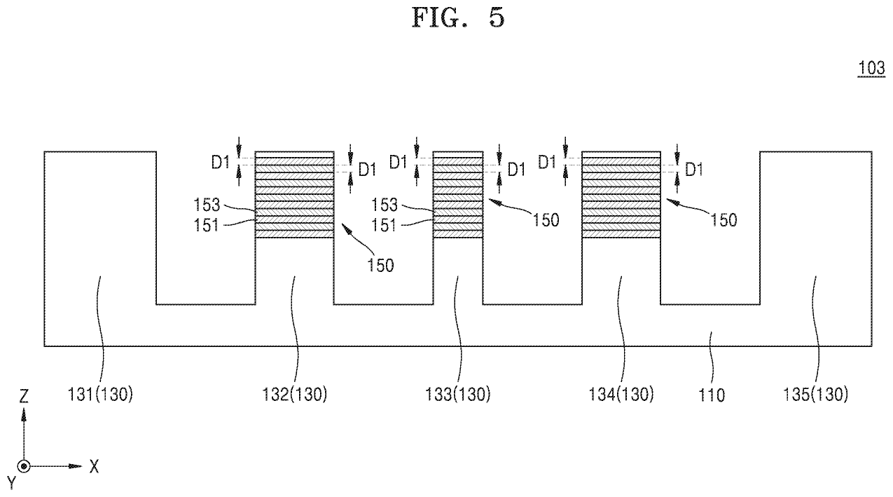

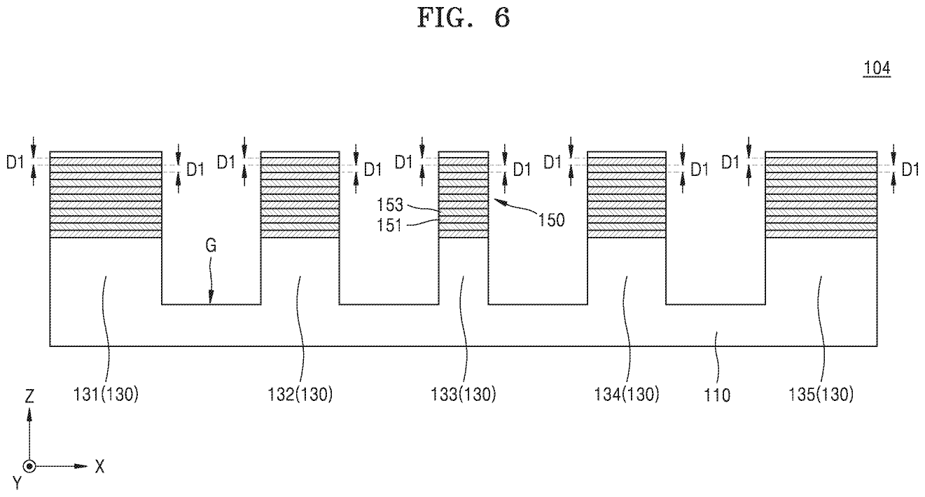

FIG. 5 is a cross-sectional view schematically illustrating a grid structure 103 for fixing a specimen according to embodiments. FIG. 6 is a cross-sectional view schematically illustrating a grid structure 104 for fixing a specimen according to embodiments. The grid structure 103 as illustrated in the example of FIG. 5 and the grid structure 104 as illustrated in the example of FIG. 6 may represent aspects of or may be represented by aspects of the grid structure 100 as described with reference to FIGS. 1 and 2, the grid structure 101 as described with reference to FIG. 3, the grid structure 102 as described with reference to FIG. 4, or a combination thereof. As such, redundant description between the grid structure 100 of FIGS. 1 and 2, the grid structure 101 of FIG. 3, the grid structure 102 of FIG. 4, the grid structure 103 of FIG. 5, and the grid structure 104 of FIG. 6 is omitted and the differences therebetween are mainly explained.

Referring to FIGS. 5 and 6, the grid structure 103 and the grid structure 104, respectively, may each include a body 110 and one or more protrusions 130. Each of the protrusions 130 may have a shape protruding in the vertical direction Z from the top surface of the body 110.

In some embodiments and in the examples of FIGS. 5 and 6, a plurality of protrusions 130 may be provided. For example, the protrusions 130 may include a first protrusion 131, a second protrusion 132, a third protrusion 133, a fourth protrusion 134, and a fifth protrusion 135. However, although five protrusions 130 are illustrated, embodiments are not limited thereto, and a number of protrusions 130 may be provided that is less than or greater than five.

As described herein, one or more first layers 151 and one or more second layers 153 may be alternately stacked on at least any two of the protrusions 130 (e.g., after the first layer 151 is formed, the second layer 153 may be formed on the first layer 151, the first layer 151 may be stacked again on the second layer 153, etc.). The number of first layers 151 and the number of second layers 153 alternately stacked may include a plurality of layers, respectively. A region in which at least one first layer 151 and at least one second layer 153 are alternately stacked may be defined as a first region 150.

In the examples of FIGS. 5 and 6, the first region 150 may be formed in at least two of protrusions 130 from among a plurality of protrusions 130. For example, the first region 150 may be formed on each of any two different protrusions 130. Additionally or alternatively, as shown in the example of FIG. 5, the first region 150 may be formed on each of any three different protrusions 130 (e.g., the second protrusion 132, the third protrusion 133, and the fourth protrusion 134 in the example of FIG. 5). Additionally or alternatively, the first region 150 may be formed on each of any four different protrusions 130. Additionally or alternatively, as shown in the example of FIG. 6, the first region 150 may be formed on all five protrusions 130.

The first regions 150 respectively formed on the plurality or subset of protrusions 130 may include one or more first layers 151 and one or more second layers 153, and the first layers 151 and the second layers 153 may all have the same thickness, which is the first thickness D1. For example, as shown in FIG. 5, when the first region 150 is formed in each of the second protrusion 132, the third protrusion 133, and the fourth protrusion 134, the thicknesses of the first layer 151 and the second layer 153 formed on the second protrusion 132 may be the same as the first thickness D1, the thicknesses of the first layer 151 and the second layer 153 formed on the third protrusion 133 may be the same as the first thickness D1, and the thicknesses of the first layer 151 and the second layer 153 formed on the fourth protrusion 134 may also be the same as the first thickness D1.

Based on the first region 150 being formed in each of the subset of the plurality of protrusions 130, each of the protrusions 130 in which the first region 150 is formed (e.g., the second protrusion 132, the third protrusion 133, and the fourth protrusion 134) may perform the magnification control and reference function described herein. Therefore, when inspecting and analyzing a plurality of specimens 10, it is possible to adjust the magnification of the electron microscope through the protrusions 130 located under each of the specimens 10 and to refer to the reference during analysis.

Additionally or alternatively, as described with reference to FIG. 6, the first regions 150 are formed on all of the first protrusion 131, the second protrusion 132, the third protrusion 133, the fourth protrusion 134, and the fifth protrusion 135, respectively, and the thickness of each of the first layers 151 and each of the second layers 153 in each first region 150 is the same as the first thickness D1. Thus, it may be easy to form a grid structure 104 for fixing a specimen.

For example, after repeatedly performing a process in which the first layer 151 may be formed on the top surface of the body 110 with the same thickness in the horizontal direction X as the top surface of the body 110, and the second layer 153 having the same thickness in the horizontal direction X may be formed on the first layer 151, grooves G may be formed through etching and mechanical drilling to thereby form a plurality of protrusions 130 on which first regions 150 are formed, respectively.

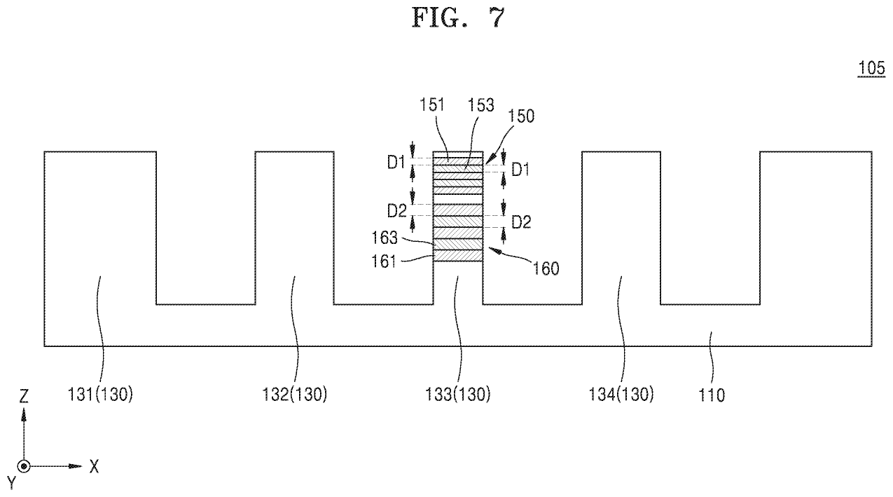

FIG. 7 is a cross-sectional view schematically illustrating a grid structure 105 for fixing a specimen according to embodiments. The grid structure 105 as illustrated in the example of FIG. 7 may represent aspects of or may be represented by aspects of the grid structure 100 as described with reference to FIGS. 1 and 2, the grid structure 101 as described with reference to FIG. 3, the grid structure 102 as described with reference to FIG. 4, the grid structure 103 as described with reference to FIG. 5, the grid structure 104 as described with reference to FIG. 6, or a combination thereof. As such, redundant description between the grid structure 100 of FIGS. 1 and 2, the grid structure 101 of FIG. 3, the grid structure 102 of FIG. 4, the grid structure 103 of FIG. 5, the grid structure 104 of FIG. 6, and the grid structure 105 of FIG. 7 is omitted and the differences therebetween are mainly explained.

Referring to FIG. 7, the grid structure 105 may include a body 110 and one or more protrusions 130.

Each of the protrusions 130 may have a shape protruding in the vertical direction Z from the top surface of the body 110. In some embodiments and in the examples of FIG. 7, a plurality of protrusions 130 may be provided. For example, the protrusions 130 may include a first protrusion 131, a second protrusion 132, a third protrusion 133, a fourth protrusion 134, and a fifth protrusion 135. However, although five protrusions 130 are illustrated, embodiments are not limited thereto, and a number of protrusions 130 may be provided that is less than or greater than five.

As described herein, one or more first layers 151 and one or more second layers 153 may be alternately stacked on at least one of the protrusions 130 (e.g., after the first layer 151 is formed, the second layer 153 may be formed on the first layer 151, the first layer 151 may be stacked again on the second layer 153, etc.). The number of first layers 151 and the number of second layers 153 alternately stacked may include a plurality of layers, respectively. A region in which at least one first layer 151 and at least one second layer 153 are alternately stacked may be defined as a first region 150.

In some embodiments and in the example of FIG. 7, one or more third layers 161 and one or more fourth layers 163 may be alternately stacked under the first region 150 in the vertical direction Z. For example, after a first instance of the third layer 161 is formed, a first instance of the fourth layer 163 may be formed on the first instance of the third layer 161, an additional instance of the third layer 161 may be stacked on the first instance of the fourth layer 163, an additional instance of the fourth layer 163 may be stacked on the additional instance of the third layer 161, etc. The number of third layers 161 and the number of fourth layers 163 alternately stacked may be include a plurality of layers, respectively. A region in which at least one third layer 161 and at least one fourth layer 163 are alternately stacked may be defined as a second region 160.

The third layer 161 and the fourth layer 163 may have the same thickness in the vertical direction Z. That is, the plurality of third layers 161 and the plurality of fourth layers 163 alternately stacked may have the same thicknesses in the vertical direction Z. The thickness may be understood as a second thickness D2.

In some embodiments, the thickness of each of the third layer 161 and the fourth layer 163 may be different from the first thickness D1, which is the thickness of each of the first layer 151 and the second layer 153. In some embodiments, the second thickness D2 may be greater than the first thickness D1, but the embodiments are not limited thereto, and the second thickness D2 may be less than the first thickness D1.

Based on the second region 160 being formed under the first region 150 in the vertical direction Z, the second region 160 may be formed in the protrusion 130 where the first region 150 is formed.

The third layer 161 and the fourth layer 163 may be formed of different materials. According to embodiments, the third layer 161 may include SiGe, and the fourth layer 163 may include Si.

The third layer 161 and the fourth layer 163 may be formed of a single crystal similar to the first layer 151 and the second layer 153 being formed of a single crystal. Additionally, the third layer 161 and the fourth layer 163 may be visually distinguished with the naked eye (e.g., and/or by an electron microscope) from each other.

Accordingly, the third layer 161 and the fourth layer 163 may serve as a scale similar to the first layer 151 and the second layer 153. However, based on the second thickness D2 (e.g., the thickness of each of the third layer 161 and the fourth layer 163) being different from the first thickness D1, the second region 160 where the third layer 161 and the fourth layer 163 are alternately formed may serve as a different scale than that of the first region 150.

In some embodiments, the second thickness D2 may be in a range of about 1 nm to about 100 nm.

In some embodiments, the first region 150 and the second region 160 may be formed adjacent to each other. For example, the second region 160 may be formed directly below the first region 150. Additionally or alternatively, the first region 150 and the second region 160 may be formed to be spaced apart from each other at predetermined intervals in the vertical direction Z.

As shown in the example of FIG. 7, the first region 150 and the second region 160 may be formed in a same protrusion 130 (e.g., the third protrusion 133). Accordingly, the magnification may be easily adjusted using the same protrusion 130. For example, when a high magnification is required, scales with a smaller thickness in the vertical direction Z may be used (e.g., the first region 150 that includes the first thickness D1 that is shown to be smaller than the second thickness D2 of the second region 160 in the example of FIG. 7), and when a low magnification is required, scales with a greater thickness in the vertical direction Z may be used (e.g., the second region 160 in the example of FIG. 7). Based on the first region 150 and the second region 160 formed on a given protrusion 130 therein having different scales, the magnification of the electron microscope may be easily adjusted.

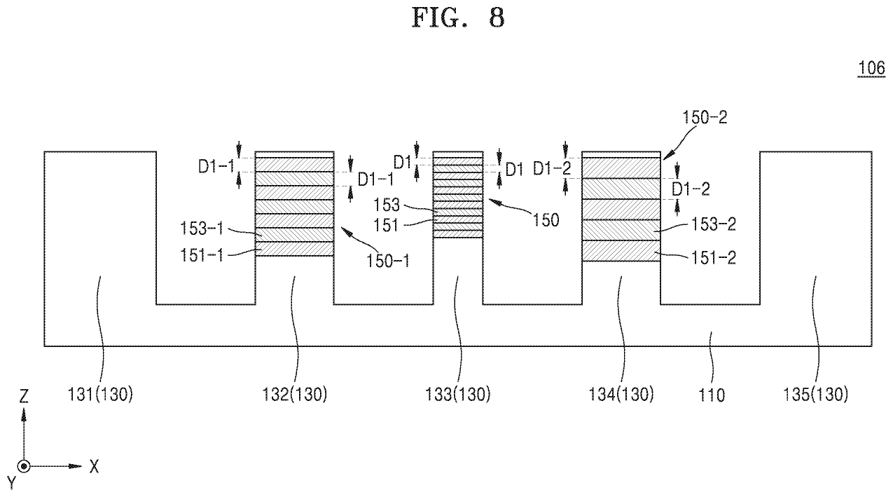

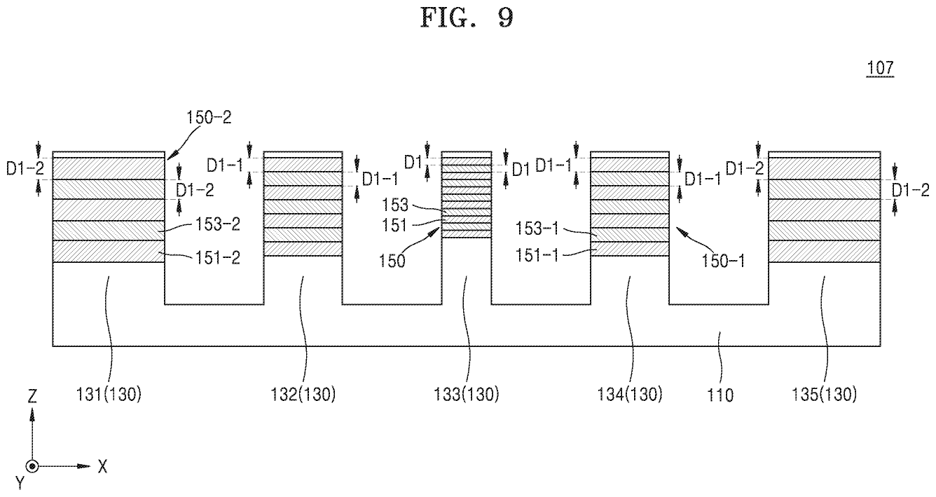

FIG. 8 is a cross-sectional view schematically illustrating a grid structure 106 for fixing a specimen according to embodiments. FIG. 9 is a cross-sectional view schematically illustrating a grid structure 107 for fixing a specimen according to embodiments. The grid structure 106 as illustrated in the example of FIG. 8 and the grid structure 107 as illustrated in the example of FIG. 9 may represent aspects of or may be represented by aspects of the grid structure 100 as described with reference to FIGS. 1 and 2, the grid structure 101 as described with reference to FIG. 3, the grid structure 102 as described with reference to FIG. 4, the grid structure 103 as described with reference to FIG. 5, the grid structure 104 as described with reference to FIG. 6, the grid structure 105 as described with reference to FIG. 7, or a combination thereof. As such, redundant description between the grid structure 100 of FIGS. 1 and 2, the grid structure 101 of FIG. 3, the grid structure 102 of FIG. 4, the grid structure 103 of FIG. 5, the grid structure 104 of FIG. 6, the grid structure 105 of FIG. 7, the grid structure 106 of FIG. 8, and the grid structure 107 of FIG. 9 is omitted and the differences therebetween are mainly explained.

Referring to FIGS. 8 and 9, the grid structure 106 and the grid structure 107, respectively, may each include a body 110 and one or more protrusions 130. Each of the protrusions 130 may have a shape protruding in the vertical direction Z from the top surface of the body 110.

In some embodiments and in the examples of FIGS. 8 and 9, a plurality of protrusions 130 may be provided. For example, the protrusions 130 may include a first protrusion 131, a second protrusion 132, a third protrusion 133, a fourth protrusion 134, and a fifth protrusion 135. However, although five protrusions 130 are illustrated, embodiments are not limited thereto, and a number of protrusions 130 may be provided that is less than or greater than five.

First regions 150, 150-1, and 150-2 may be formed on a subset of the plurality of protrusions 130, respectively. For example, the first regions 150, 150-1, and 150-2 formed in each of the respective protrusions 130 may have scales having different thicknesses.

As illustrated in the example of FIG. 8, the third protrusion 133 may include a first region 150 in which a first layer 151 and a second layer 153 are formed, where the thicknesses of both the first layer 151 and the second layer 153 in the first region 150 may be the first thickness D1. Additionally, the second protrusion 132 may include a first region 150-1 in which a first layer 151-1 and a second layer 153-1 are formed, where each of the thicknesses of the first layer 151-1 and the second layer 153-1 in the first region 150-1 may be a third thickness D1-1. Additionally, the fourth protrusion 134 may include a first region 150-2 in which a first layer 151-2 and a second layer 153-2 are formed, where each of the thicknesses of the first layer 151-2 and the second layer 153-2 may be a fourth thickness D1-2.

In some embodiments, the first thickness D1, the third thickness D1-1, and the fourth thickness D1-2 may all be different from each other.

Accordingly, an effect of having a different thickness scale may appear for each of the protrusions 130 based on the different thicknesses of the respective layers. For example, as necessary, specimens requiring a high magnification may be inspected at a thin protrusion 130 (e.g., with a smaller thickness for each of the respective layers), and specimens requiring a low magnification may be inspected at a thick protrusion 130 (e.g., with a larger thickness for each of the respective layers), increasing the efficiency of the specimen inspection.

In the example of FIG. 9, all the protrusions 130 include at least one of the first regions 150, 150-1, and 150-2. For example, the first and fifth protrusions 131 and 135 may include the first region 150-2 (e.g., and corresponding fourth thickness D1-2 for the first layers 151-2 and the second layers 153-2) and may have the same scale. Additionally or alternatively, the second and fourth protrusions 132 and 134 may include the first region 150-1 (e.g., and corresponding third configured thickness D1-1 for the first layers 151-1 and the second layers 153-1) and may have the same scale. Additionally or alternatively, the third protrusion 133 may include the first region 150 (e.g., and corresponding first configured thickness D1 for the first layers 151 and the second layers 153) and may have a scale different from those of the first protrusion 131, the second protrusion 132, the fourth protrusion 134, and the fifth protrusion 135. However, the embodiments are not limited thereto, and all of the protrusions 130 may have scales having different thicknesses.

While the inventive concept has been particularly shown and described with reference to embodiments thereof, it will be understood that various changes in form and details may be made therein without departing from the spirit and scope of the following claims.

What is claimed is:

1. An apparatus for fixing a specimen, the apparatus comprising:
a body; and
a plurality of protrusions protruding in a vertical direction on a top surface of the body, wherein:
at least one of the protrusions comprises a first region in which at least one first layer and at least one second layer are alternately stacked in the vertical direction, and
the at least one first layer and the at least one second layer each have a first thickness in the vertical direction.

2. The apparatus of claim 1, wherein the at least one first layer and the at least one second layer are formed of a single crystal.

3. The apparatus of claim 1, wherein the at least one first layer comprises silicon germanium and the at least one second layer comprises silicon.

4. The apparatus of claim 1, wherein the first thickness is in a range of about 1 nm to about 100 nm.

5. The apparatus of claim 1, wherein
the protrusion having the first region formed therein further comprises a second region below the first region in the vertical direction, and
the second region comprises at least one third layer and at least one fourth layer alternately stacked in the vertical direction.

6. The apparatus of claim 5, wherein
each of the at least one third layer and the at least one fourth layer has a second thickness in the vertical direction, and
the second thickness is different from the first thickness.

7. The apparatus of claim 5, wherein
the at least one first layer and the at least one third layer each comprise silicon germanium, and
the at least one second layer and the at least one fourth layer each comprise silicon.

8. The apparatus of claim 5, wherein the at least one first layer, the at least one second layer, the at least one third layer, and the at least one fourth layer are formed of a single crystal.

9. The apparatus of claim 1, wherein
the apparatus comprises five protrusions, and
at least two of the protrusions have a different thicknesses in a horizontal direction.

10. The apparatus of claim 1, wherein each of at least two of the protrusions comprises the first region in which at least one first layer and at least one second layer are alternately stacked in the vertical direction.

11. The apparatus of claim 10, wherein
the at least one first layer and the at least one second layer, formed in any one of the protrusions in which the first region is formed, each have the first thickness in the vertical direction, and
the at least one first layer and the at least one second layer, formed in another of the protrusions in which the first region is formed, each have a third thickness in the vertical direction different from the first thickness.

12. An apparatus for fixing a specimen, the apparatus comprising:
a body; and
a plurality of protrusions protruding in a vertical direction on a top surface of the body, wherein
at least one of the protrusions comprises a first region in which at least one first layer and at least one second layer are alternately stacked in the vertical direction,
the at least one first layer comprises silicon germanium and the at least one second layer comprises silicon,
each of the at least one first layer and the at least one second layer has a first thickness in the vertical direction, and
the at least one first layer and the at least one second layer are formed of a single crystal.

13. The apparatus of claim 12, wherein the first thickness is in a range between 1 nm to 100 nm.

14. The apparatus of claim 12, wherein
the protrusion having the first region formed therein further comprises a second region below the first region in the vertical direction, and
the second region comprises at least one third layer and at least one fourth layer alternately stacked in the vertical direction.

15. The apparatus of claim 14, wherein
each of the at least one third layer and the at least one fourth layer has a second thickness in the vertical direction, and
the second thickness is different from the first thickness.

16. The apparatus of claim 12, wherein each of at least two of the protrusions comprises the first region in which at least one first layer and at least one second layer are alternately stacked in the vertical direction.

17. The apparatus of claim 16, wherein
the at least one first layer and the at least one second layer, formed in any one of the protrusions in which the first region is formed, each have the first thickness, and
the at least one first layer and the at least one second layer, formed in another of the protrusions in which the first region is formed, each have a third thickness in the vertical direction that is different from the first thickness.

18. An apparatus for fixing a specimen, the apparatus comprising:
a body; and
at least five protrusions protruding in a vertical direction on a top surface of the body, wherein
each of the protrusions comprises a first region in which at least one first layer and at least one second layer are alternately stacked in the vertical direction,
the at least one first layer comprises silicon germanium and the at least one second layer comprises silicon,
each of the at least one first layer and the at least one second layer has a first thickness in the vertical direction, and
the at least one first layer and the at least one second layer are formed of a single crystal.

19. The apparatus of claim 18, wherein
each of the at least five protrusions further comprise a second region below the first region in the vertical direction,
the second region comprises at least one third layer and at least one fourth layer alternately stacked in a vertical direction,
each of the at least one third layer and the at least one fourth layer has a second thickness in the vertical direction, and
the second thickness is different from the first thickness.

20. The apparatus of claim 19, wherein
the first thickness is in a range between 1 nm to 100 nm, and
the second thickness is in the range between 1 nm to 100 nm.
